(19) United States
(12) Patent Application Publication
(10) Pub. No.: US 2014/0368275 A1
(43) Pub. Date: Dec. 18, 2014

(54) AMPLIFIER IN DOHERTY CONFIGURATION COMPRISING A DEVICE FOR VARYING THE WORKING FREQUENCY AND METHOD THEREOF

(71) Applicant: ONETASTIC S.R.L., Brescia (BS) (IT)

(72) Inventor: Carlo Bombelli, Roncadelle (IT)

(73) Assignee: ONETASTIC S.R.L., Brescia (BS) (IT)

(21) Appl. No.: 14/363,726

(22) PCT Filed: Dec. 7, 2012
(86) PCT No.: PCT/IB2012/057060

§ 371 Date: Jun. 6, 2014

(30) Foreign Application Priority Data
Dec. 7, 2011 (IT) TO2011A001123

(51) Int. Cl. H03F 3/24; H01P 9/00; H03F 3/19

(52) U.S. Cl. CPC H03F 3/245; H03F 3/19; H01P 9/00; H03F 2200/315; H03F 2203/21139
USPC 330/295

(57) ABSTRACT

An amplifier in Doherty configuration includes a circuit (32) having a delay line consisting of a constant-impedance transmission line (12) and a device (10) adapted to vary the electric length of the transmission line (12). The device (10) includes a metallic body (14) with an outer wall (16) and an inner wall (22) adapted to define a cavity (20). The walls (16,22) define a slot (24). The cavity (20) includes a first portion (21) having a first cross-section and a second portion (23) having a second cross-section which is greater than the first cross-section, the second portion (23) includes a dielectric element (27) with a cutout (25) corresponding to the slot (24), the first (21) and second (23) portions extending in the longitudinal direction of the device (10) and the transmission line being provided, inside the first portion (21) and inside the second portion (23), in the cutout (25) of the dielectric element (27), the dielectric element (27) occupying the cavity (20) of the second portion (23), and including a translator (11) adapted to translate the dielectric element (27) on the circuit (32) in the longitudinal direction of the device (10).

The present invention relates to an amplifier in Doherty configuration comprising a device adapted to vary its operating frequency, and a method thereof.

More specifically, the present invention relates to an amplifier in Doherty configuration comprising a circuit having a delay line consisting of a constant-impedance transmission line and a device adapted to vary the electric length of said transmission line.

Applications are known in the art which require the presence of a circuit element capable of introducing a variable delay along the path of a signal.

At present, this requirement is typically met in a few different ways.

The simplest way of introducing a delay along the path of a signal is to have said signal transit along a constant-impedance line having such a length that said signal, travelling at a speed equal to the typical speed of the physical medium, takes a time equal to the desired delay to cover the conductive element involved. An alternative way is to have said signal transit along a constant-impedance line the electric length of which is varied by changing the material, and hence the dielectric constant thereof, used for making the line itself, since the wave propagation speed is related to the dielectric constant of the material which the dielectric substance is made of.

In order to avoid any signal alterations, the line must have a known constant impedance compatible with the surrounding circuit elements.

The delay is typically made variable in two ways:

1) the physical length of the line is modified, thus also modifying the length of the conductive element because, all other conditions being equal, if the physical length of the conductive element is doubled, the delay being introduced will be doubled as well; or

2) the electric length of the line itself is modified.

The electric length A of a circuit is the relationship existing between that circuit and the length of the electromagnetic wave that goes through it or is treated by it. Said wavelength, defined by letter A, is bound to the wave frequency f and to the mechanical dimensions of the circuit or line by the following relation:

Λ=L/λ=f·L/c

where L is the greatest dimension of the circuit taken into account, e.g. the longest track to be travelled by the electromagnetic waves involved.

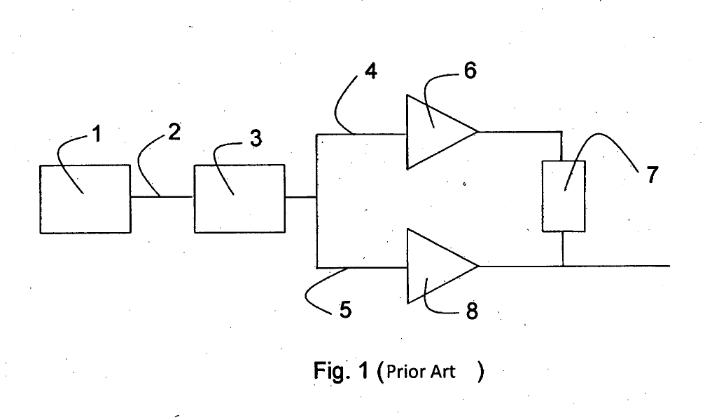

One application that requires the possibility of changing the electric length introduced along the signal path is the utilization of a Doherty amplifier to create, for example, a television transmitter capable of operating over a wide frequency range while still ensuring a level of efficiency close to the ideal one. FIG. 1 shows a block diagram of a Doherty amplifier. An input signal 2, generated by a signal source 1, is divided into two separate output signals 4,5 offset by 90° by means of a hybrid coupler 3 or a similar element.

The two output signals 4,5 are then applied to the input of two respective different amplifiers 6,8, which, being differently polarized (typically one as Class AB for the carrier and at least one as Class C for the peak), must then be recombined to recover the phase difference applied to the input.

To do so, an additional line 7 of electric length equal to ¼ of the wave of the frequency of the input signal 2 is normally used, which, in addition to the correct phase, also ensures insulation between the two amplifiers 6,8 by acting as an impedance inverter.

It is the physical length of this line that represents the usable bandwidth limit of the Doherty amplifier, which is typically as low as 40 or 50 MHz.

The Doherty scheme, therefore, while offering interesting advantages in terms of efficiency and power density, can only be used for relatively narrow-band applications.

One example of such a Doherty amplifier comprising a delay line is known from US patent application No. US 2011/0193624.

Said patent application proposes to vary the electric length of the line to an electric length equal to ¼ of the wave of the frequency of the input signal by mechanically lengthening or shortening it by means of sliding contacts, i.e. by sliding a pair of conductive contacts on a track that forms the transmission line. Depending on the point of contact, the physical length of the path will change. However, the mechanism described in said US patent application may lead to malfunctions over time, because problems may arise due to oxidation and false contacts.

Furthermore, in order to change the electric length, it is necessary to remove the screws that secure the upper part of the device in a predetermined position; this typically also implies the necessity of dismounting the amplifier casing by removing the fastening screw thereof. As a consequence, the device of said US patent application cannot be servocontrolled.

Finally, the solution disclosed in said US patent application is complex from a practical viewpoint, because it requires the assembling of many components, such as rubber discs, adhesive, printed circuit, and the like.

It is therefore the object of the present invention to provide an amplifier in Doherty configuration comprising a device adapted to vary its operating frequency, and a method thereof, which can be easily and economically implemented.

It is a further object of the present invention to provide an amplifier in Doherty configuration comprising a device adapted to vary its operating frequency, and a method thereof, wherein the operating frequency can be adjusted without having to turn off the amplifier.

These and other objects of the invention are achieved through an amplifier in Doherty configuration comprising a device adapted to vary its operating frequency, and a method thereof, as set out in the appended claims, which are an integral part of the present description.

In brief, the present invention allows varying the electric length of a delay line consisting of a constant-impedance transmission line of an amplifier in Doherty configuration, by modifying the dielectric constant of the transmission line itself while keeping the impedance constant. In fact, the electric length introduced by a constant-length transmission line is affected by the length of the transmission line itself and also by the dielectric constant εᵣ of the material it is made of.

Given a constant-impedance transmission line having a fixed length L, the dielectric constant of the line material can be varied by immersing at least a portion thereof into a dielectric medium having a second dielectric constant which is greater than the dielectric constant of the air in which the remaining line portion is immersed.

Other dielectric constants may be used and taken into account, and air may be replaced, for example, with other materials having a different dielectric constant, without prejudice to the principle and scope of the invention. It is therefore sufficient to utilize two different materials having a different dielectric constant. By modifying the length of the portion of conductive element immersed in the material characterized by the second dielectric constant, the electric length of the element itself is changed. In order to keep the line impedance constant, the conductive element is positioned into the cavity of a device having controlled dimensions, such as to retain a constant impedance.

Further features of the invention are set out in the appended claims, which are intended to be an integral part of the present description.

The above objects will become more apparent from the following detailed description, of an amplifier in Doherty configuration comprising a device adapted to vary its operating frequency, and a method thereof, with particular reference to-the annexed drawings, wherein:

FIG. 1 is a diagram of a prior-art Doherty amplifier;

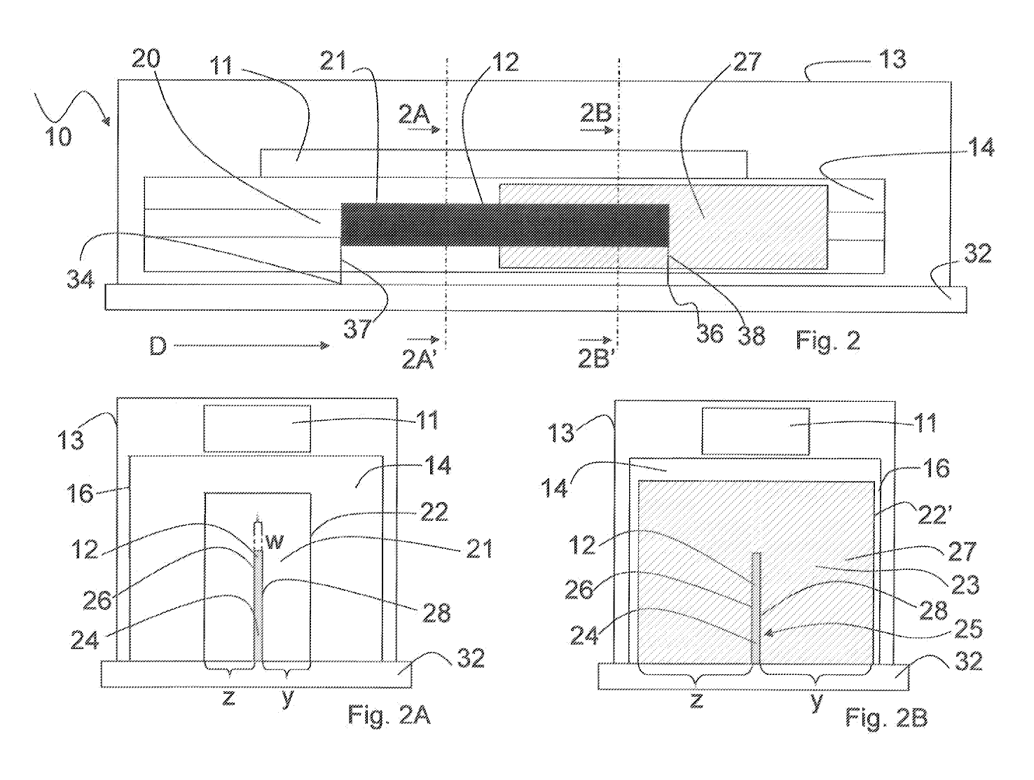

FIG. 2 is a longitudinal sectional view of a device for varying the electric length of a signal transmission line;

FIGS. 2a and 2b are sectional views along the lines 2a-2a and 2b-2b′; respectively, of FIG. 2;

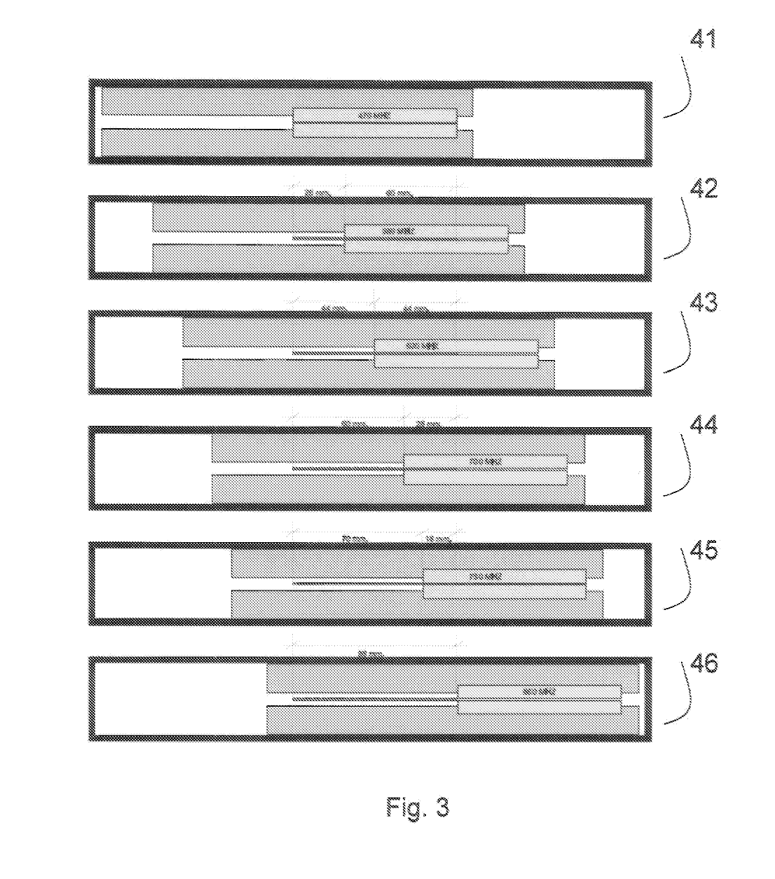

FIG. 3 shows various modes of operation of the device according to the present invention.

With reference to FIGS. 2, 2a and 2b, there is shown a device 10 for varying the electric length of a constant-impedance transmission line 12, in particular a transmission line having substantially constant thickness and width, adapted to transport an electric signal.

The device 10 comprises a metallic body 14, e.g. made of aluminium or steel, extending in a substantially longitudinal direction D.

The device 10 may comprise a casing 13, the function of which is to shield the device 10 from the environment outside the casing 13.

The metallic body 14 has an outer wall 16, preferably with a constant cross-section, and an inner wall 22,22′ that defines a cavity 20.

The outer wall 16 and the inner wall 22,22′ are interrupted in a manner such as to define a slot 24. The cavity 20 and the slot 24 extend along at least a portion of the length of the device 10.

The cavity 20 comprises a first portion 21 having a first cross-section and a second portion 23 having a second cross-section which is greater than the first cross-section.

The second portion 23 of the cavity 20 comprises a dielectric element 27 with a cutout 25 corresponding to the slot 24 of the metallic body 14.

The dielectric element 27 occupies the second portion 23 of the cavity 20 and is made of a dielectric material, e.g. nylon, having a greater dielectric constant than air.

In a preferred embodiment of the invention, to which the following numerical example will refer, the metallic body 14 is a parallelepipedon, and the first and second cross-sections of the cavity 20 are rectangular or square.

As an alternative, the metallic body 14 is cylindrical, and the first and second cross-sections of the cavity 20 are circular.

The device 10 further comprises translating means 11 integral with the metallic body 14, which allow the metallic body 14 to be translated along the longitudinal direction D.

The translating means 11 may, for example, be moved manually or by means of a pinion/worm screw motor reducer system or a step motor (neither of which are shown) or other drive systems, whether electric or pneumatic.

The translating means 11 can therefore be controlled from the outside of the metallic body 14 to act, through a suitable mechanical connection, upon the dielectric element 27 in such a way as to translate the dielectric element 27 itself, which can slide within the metallic body 14, in the longitudinal direction D.

The following will illustrate a method according to the invention for varying the electric length of a constant-impedance transmission line 12.

With reference to FIG. 2a, it is assumed that the transmission line 12 has a section of thickness w and that a first edge 26 thereof is at a first distance z from the inner wall 22 of the metallic body 14 and a second edge 28 thereof is at a second distance y from the inner wall 22 of the metallic body 14: in this case, the first section d of the first portion 21 of the cavity 20 will be d=z+w+y.

If the first distance z equals the second distance y, then the impedance along the transmission line 12 will remain constant. For example, assuming that the dielectric medium is air, that the thickness w of the transmission line 12 is 1 mm, and that the width of the transmission line 12 is approx. 7.5 mm, in order to obtain an impedance of 50 Ω the first distance z and the second distance y will have to, be set to 3 mm. The first portion 21 of the cavity 20 will therefore act as an air gap around the transmission line 12 immersed in a first dielectric medium, in particular air.

Similar considerations apply to the second portion 23 of the cavity 20.

With reference to FIG. 2b, in order to keep the impedance of the conductive element 12 constant, it is sufficient, in fact, to impose that the distance z′ of the first edge 26 of the conductive element 12 from the inner wall 22′ of the metallic body 14 and the distance y′ of the second edge 28 of the conductive element 12 are equal. For example, assuming that the dielectric material is nylon having a dielectric constant of 2.9, that the impedance required is still of 50 ohm, and that the dimensions of the transmission line 12 are still the same, it will be sufficient to impose that z′=y′=6.65 mm.

By applying simple solid geometry rules, one can obtain that the impedance has a constant value along the entire longitudinal extension of the metallic body 14. More in general, it must be ensured that the transmission line 12 is positioned centrally within the cavity 20, and that its edges 26,28 are equidistant from the inner wall 22,22′ of the metallic body 14.

By sliding the metallic body 14 on the transmission line 12, the electric length of the line itself will be changed.

With reference to FIG. 3, there is shown a diagram that illustrates the effect obtained upon the transmission line 12 by the device 10 according to the invention.

In a first operating position 41, the metallic body 14 is positioned in such a way that the transmission line 12 is completely immersed in the second dielectric medium, in particular nylon.

In a sixth operating position 46, the metallic body 14 is positioned in such a way that the transmission line 12 is completely immersed in the first dielectric medium, in particular air.

In the intermediate positions 42,43,44 and 45, a first portion of the element of the transmission line 12 is immersed in the first dielectric medium and a second portion of the transmission line 12 is immersed in the second dielectric medium. As the frequency of the signal travelling over the transmission line 12 changes, the metallic body 14 is simply translated along the transmission line 12 to the required position. The impedance of the transmission line 12 will remain constant thanks to the geometric construction of the device 10.

In the example shown in FIG. 3, it is assumed that the first dielectric medium is air and the second dielectric medium is nylon.

The position 41 illustrate the case wherein the frequency of the signal travelling over the transmission line 12, the length of which is 88 mm, is 470 MHz. It can be observed that the whole transmission line 12 is immersed in the second dielectric medium.

If the frequency of the signal travelling over the line has to be changed to 580 MHz (position 42), the metallic body 14 will be translated by 28 mm to the right from the position 41, so that a 28 mm line portion will be immersed in air, while the remaining 60 mm line portion will be immersed in nylon.

If the frequency of the signal travelling over the line has to be changed to 630 MHz (position 43), the metallic body 14 will be translated by 44 mm to the right from the position 41, so that a 44 mm line portion will be immersed in air, while the remaining 44 mm line portion will be immersed in nylon.

If the frequency of the signal travelling over the line has to be changed to 700 MHz (position 44), the metallic body 14 will be translated by 60 mm to the right from the position 41, so that a 28 mm line portion will be immersed in air, while the remaining 44 mm line portion will be immersed in nylon.

If the frequency of the signal travelling over the line has to be changed to 750 MHz (position 45), the metallic body 14 will be translated by 70 mm to the right from the position 41, so that a 70 mm line portion will be immersed in air, while the remaining 18 mm line portion will be immersed in nylon.

If the frequency of the signal travelling over the line has to be changed to 860 MHz (position 46), the metallic body 14 will be translated by 88 mm to the right from the position 41, so that the whole conductive element 12 will be immersed in air.

It is apparent from the above that implementing a delay line created by means of the device 10 and a constant-impedance transmission line 12 in a Doherty amplifier can be very useful.

In fact, in order to implement a line whose electric length must be varied between any two points 34,36 of a circuit 32, e.g. a printed circuit, it will be sufficient to electrically connect the points 34,36 of the circuit 32 by means of a constant-impedance transmission line comprising a transmission line portion 12 covered by the device 10 and two connecting conductive elements 37,38 that connect said points 34,36 to the transmission line portion 12 covered by the device 10.

In particular, if the delay line is one of a Doherty amplifier, then the device 10 according to the invention advantageously allows varying the operating frequency of the amplifier without having to replace the λ/4 line. In fact, it will be sufficient to translate the device 10 along the transmission line 12 so as to adjust it to the new frequency of the signal travelling over the transmission line 12, as shown in FIG. 3.

The features of the present invention, as well as the advantages thereof, are apparent from the above description.

A first advantage of the amplifier in Doherty configuration with adjustable operating frequency in accordance with the present invention is that it can be manufactured in a simple and economical manner.

A second advantage of the device and method according to the present invention is that they can be both implemented in a new or an existing circuit.

A further advantage of the device and method according to the present invention is that the electric length of the conductor can be adjusted without having to turn off the amplifier that comprises such a device.

The amplifier in Doherty configuration comprising a device adapted to vary its operating frequency, and the method thereof, described herein by way of example may be subject to many possible variations without departing from the novelty spirit of the inventive idea; it is also clear that in the practical implementation of the invention the illustrated details may have different shapes or be replaced with other technically equivalent elements.

For example, also the first portion 21 of the cavity 20 may be filled with a dielectric material having a cutout corresponding to the slot 24, provided that the dielectric material has a different (e.g. lower) dielectric constant than the second portion 23 of the cavity 20.

For example, dielectric materials other than nylon may be used, in particular fiberglass-based materials.

For example, the present invention may be exploited to create an amplification system comprising one or more circuits 32 housing one or more respective amplifiers adapted to amplify one same signal. The outputs of said amplifiers are combined together in order to increase the gain of the amplification system, and transit on a single delay line consisting of a constant-impedance transmission line 12, thereby allowing the operating frequency of said amplification system to be adjusted by acting upon a single adjustment point, by using a device 10 designed as previously described.

An amplifier in Doherty configuration or an amplification system as described above may advantageously be implemented in a transmitter.

It can therefore be easily understood that the present invention is not limited to an amplifier in Doherty configuration comprising a device adapted to vary its operating frequency, and a method thereof, but may be subject to many modifications, improvements or replacements of equivalent parts and elements without departing from the inventive idea, as clearly specified in the following claims.

1. An amplifier in Doherty configuration, comprising:
a circuit having a delay line consisting of a constant-impedance transmission line and a device adapted to vary the electric length of said transmission line,
wherein said device comprises a metallic body with an outer wall and an inner wall adapted to define a cavity, said walls being interrupted in a manner such as to define a slot, said cavity and said slot extending along at least a portion of the length of said device,
wherein said cavity comprises a first portion having a first cross-section and a second portion having a second cross-section which is greater than said first cross-section, said second portion comprising a dielectric element with a cutout corresponding to said slot, said first and second portions extending in the longitudinal direction of said device and said transmission line being provided, inside said first portion and inside said second portion, in said cutout of said dielectric element, said dielectric element being adapted to occupy the cavity (20) of said second portion, and in that it comprises translating means integral with said metallic body and adapted to translate said dielectric element on said circuit in the longitudinal direction of said device.

2. An amplifier according to claim 1, wherein said metallic body is a parallelepipedon, and said first and second cross-sections are rectangular or square.

3. An amplifier according to claim 1, wherein said metallic body is cylindrical, and said first and second cross-sections are circular.

4. An amplifier according to claim 1, wherein said dielectric element is made of a material having a relative dielectric constant greater than 1.

5. An amplifier according to claim 4, wherein said material is nylon or a fiberglass-based material.

6. An amplifier according to claim 1, wherein said first portion of the cavity comprises a second dielectric element with a cutout corresponding to said slot, said second dielectric element being adapted to occupy the cavity of said first portion, and said second dielectric element having a different dielectric constant than a dielectric constant of said dielectric element.

7. An amplifier according to claim 1, wherein said device comprises a casing adapted to shield said device from the environment outside said casing.

8. An amplifier comprising a delay line, wherein said delay line consists of a transmission line, and wherein said delay line is positioned in a cavity of a device claim 1.

9. An amplifier according to claim 8, wherein said transmission line is positioned centrally in said cavity, so that its edges are equidistant from said inner wall.

10. An amplification system comprising:
one or more circuits housing one or more respective amplifiers adapted to amplify one same signal,
wherein the outputs of said amplifiers are combined together in order to increase the gain of said amplification system, and
wherein said outputs of said amplifiers travel over a single delay line consisting of a constant-impedance transmission line, thereby allowing the operating frequency of said amplification system to be adjusted by acting upon a single adjustment point, said amplification system further comprising a device adapted to vary the electric length of said transmission line,
wherein said device comprises a metallic body with an outer wall and an inner wall adapted to define a cavity, said walls being interrupted in a manner such as to define a slot, said cavity and said slot extending along at least a portion of the length of said device,
wherein said cavity comprises a first portion having a first cross-section and a second portion having a second cross-section which is greater than said first cross-section, said second portion comprising a dielectric element with a cutout corresponding to said slot, said first and second portions extending in the longitudinal direction of said device and said transmission line being provided, inside said first portion and inside said second portion, in said cutout of said dielectric element, said dielectric element being adapted to occupy the cavity of said second portion, and comprising translating means integral with said metallic body and adapted to translate said dielectric element on said circuit in the longitudinal direction of said device.

11. A transmitter comprising an amplifier according to claim 1.

12. A method for varying the operating frequency of an amplifier in Doherty configuration comprising:
a circuit having a delay line consisting of a constant-impedance transmission line and a device adapted to vary the electric length of said transmission line, said method comprising:
positioning said transmission line into a cavity of a device comprising a metallic body with an outer wall and an inner wall adapted to define said cavity, said walls being interrupted in a manner such as to define a slot, said cavity and said slot extending along at least a portion of the length of said device,
wherein said cavity comprises a first portion having a first cross-section and a second portion having a second cross-section which is greater than said first cross-section, said second portion comprising a dielectric element with a cutout corresponding to said slot, said first and second portions extending in the longitudinal direction of said device and said transmission line being provided, inside said first portion and inside said second portion, in said cutout of said dielectric element, said dielectric element being adapted to occupy the cavity of said second portion;
translating said device on said circuit in the direction of its length through translating means integral with said metallic body, so as to obtain the desired operating frequency.

13. A method according to claim 12, wherein said transmission line is positioned centrally in said cavity, so that its edges are equidistant from said inner wall.

14. A transmitter comprising an amplification system according to claim 10.
